(19) United States
(12) Patent Application Publication
(10) Pub. No.: US 2009/0199152 A1
(43) Pub. Date: Aug. 6, 2009

(54) Methods and apparatuses for reducing mura effects in generated patterns

(75) Inventor: Fredrik Sjostrom, Taby (SE)

Correspondence Address: HARNESS, DICKEY & PIERCE, P.L.C., P.O. BOX 8910, RESTON, VA, 20195, US

(73) Assignee: Micronic Laser Systems AB

(21) Appl. No.: 12/068,412

(22) Filed: Feb. 6, 2008

(51) Int. Cl. G06F 17/50; G03F 1/14; G21G 5/00

(52) U.S. Cl. 716/21; 430/30; 250/492.1

(57) ABSTRACT

A method for generating a pattern on a workpiece is provided. In one method for generating a pattern on a workpiece, at least two sweeps or exposure fields are calibrated based on at least two different calibration maps. The pattern is generated on the workpiece by exposing the workpiece using the at least two sweeps or exposure fields.

### BACKGROUND

### Description of the Conventional Art

During production of a photomask (e.g., a photo-reticle) or during direct patterning of a substrate, wafer or the like, a pattern generator creates a desired pattern on a workpiece.

Conventional pattern generators periodically expose a photomask to one or more optical beam(s), particle beam(s) or illumination (exposure) fields in a systematic manner. A conventional pattern generator, which periodically exposes a workpiece to exposure fields in a systematic manner, is referred to herein as an exposure field type system. A conventional pattern generator that exposes the photomask to one or more optical or particle beams is referred to herein as a scanning pattern generator.

In an exposure field type system, the fields may be created by, for example, an analogue or digital Spatial Light Modulator (SLM, DMD), a Grating Light Valve (GLV), a Liquid Crystal controlled light Valve or the like.

FIG. 1 illustrates views of a conventional exposure field based pattern generator as described in U.S. Pat. No. 7,150,949, the entire contents of which is incorporated herein by reference. Such a pattern generator is well-known in the art and will not be described in detail.

FIG. 2 illustrates a portion of a conventional exposure field based pattern generator in more detail. Referring to FIG. 2, a control signal CS output from the field generating control unit 212 to the exposure field generating device (including, e.g., an analogue or digital SLM, GLV, LC valve, or the like and focusing optics (FO)) 222) is normally referred to as a “calibration map.”

FIGS. 3A and 3B illustrate additional examples of conventional scanning pattern generators. The conventional scanning pattern generators such as those shown in FIGS. 3A and 3B scan or “sweep” a laser or particle beam, while modulating the light intensity or particle flow to control exposure of the photomask.

In a scanning pattern generator, the scanning or sweeping of one or more beams may be provided by, for example, a movable mirror, acousto-optical components as illustrated in FIGS. 4A and 4B, gratings, mechanical motion provided by a stage or carrier or the like. In this type of system, iterations or repetitions of the scanning or sweeping, along with an offset in a direction essentially perpendicular to the scanning direction are used to create the pattern.

FIG. 5 is a simplified schematic diagram of a conventional scanning pattern generator. Because conventional scanning pattern generators, such as the pattern generators shown in FIGS. 3A, 3B, 5 and the portions shown in FIGS. 4A and 4B are well-known, only a relatively brief discussion will be set forth herein.

Referring to FIG. 5, the pattern generator may be a micro-lithographic writing device for writing on photosensitive substrates with relatively high precision. The term “writing” should be understood in a broad sense, meaning, for example, exposure of photoresist and photographic emulsion, but also referring to the affect or action of light or particles on other light or particle sensitive media such as dry-process paper, by ablation or chemical processes activated by light or heat. Moreover, “light” is not limited to mean visible light, but a wide range of wavelengths from infrared to extreme ultra-violet (EUV) light. In addition, as is well-known, particle beam (e.g. E-beam, Ion-beam, or the like) based systems may be used instead of light-based systems.

As shown in FIG. 5, the pattern generator may include an electromagnetic radiation or light source 51. The light source may be a laser emitting one or more beams of electromagnetic radiation. The laser source may be pulsed or continuous in nature. The pattern generator may further include a first lens 52 for shaping the emitted beam(s), a modulator 53 to produce the desired pattern to be written, an AOD 57 to create a sweep and direct the beams towards the substrate 56, and a lens 55 to focus the beams before reaching the substrate 56 and a mirror 54. The modulator 53 may be controlled according to input data. In this example, the scanning device 57 is an acoustic optical crystal used for scanning operations to sweep the beam along scan lines on the substrate.

The scanning device may be controlled via an electrical ramp signal. If an acousto-optical deflector is used, the scanning operation is provided by a frequency ramp provided to the crystal. Although the control signal for any scanning operation may be referred to as a “ramp,” the signature of such a signal, or group of signals, may have arbitrary signatures depending on the actual means of deflection.

Conventionally, other devices such as a rotating polygon, rotating prism, rotating hologram, an acousto-optic deflector, an electro-optic deflector, a galvanometer, an electrical field controller or any similar device may be used. Raster scanning and/or spatial light modulators may also be used.

The substrate is preferably arranged on an object table, which may move in one or more directions relative to the optical writing system using, for example, electrical servo motors, air bearings or the like. The substrate may also be stationary during patterning while the optical writing system is moved in order to cover the entire target area.

FIG. 6 illustrates a portion of a scanning operation used to form a plurality of scan strips. As shown, multiple scan lines or “sweeps” may form a scan strip, and numerous scan strips may be utilized to build or generate the desired pattern on the workpiece. The length of a scan line may constitute the full width of the workpiece to be patterned.

A mask, reticle, substrate, wafer or panel written using conventional pattern generators may suffer from visual or non-visual variations in light intensity when observed in transmitted or reflected light. These variations are generally referred to as mura. Patterns themselves may vary as a result of periodical or non-periodical differences in, for example, Critical Dimension (CD) or positioning of features. In 3-D patterning the variance in the z-direction may constitute these pattern variations. These defects are commonly referred to as “mura artifacts,” and may lead to, for example, spatially varying luminescence in finished displays, varying sensitivity in image sensors or timing differences in memories, etc.

Mura artifacts may have different signatures. For example, mura artifacts may display single instance behavior, random behavior or a systematic behavior. Systematic mura artifacts may be caused by a number of inherent systematic error sources in a pattern generator. Such systematic error sources include, for example, inherent pitches or distances, pixel size, the address grid, the length of a scan line, dimensions of an exposure field and the patterns to be written in some cases may have a cyclical or substantially cyclical behavior or at least a given or predetermined distribution of set pitches. This mura is presented like a variance of the pattern with certain spatial frequencies or pitches. The pitch or pitches of these imperfections or differences in the written pattern is determined by the beat frequency between the in the writing system inherent pitches and the pattern pitches.

Systematic mura may also be directly related to errors in pattern generator. For example, imperfections in scan velocity, positioning of individual pixels, power distribution along a scan line, power distribution in an exposure field, the stitching of scan lines, scan strips or exposure fields may lead directly to mura artifacts.

In a more specific example, if sweeps of a conventional pattern generator are correlated (e.g., if a first sweep is calibrated and the ramp controlling this sweep or scan line, or copies thereof, is used for all subsequent sweeps or scan lines), the correlation may cause pattern variations in the portions of the pattern generated by the first sweep to periodically recur in portions of the pattern generated by subsequent sweeps.

In another specific example, if exposure fields of a conventional pattern generator are correlated (e.g., if a first exposure field is calibrated and the calibrating map controlling this exposure field, or copies thereof, is used for all subsequent field exposures), the correlation may cause pattern variations in the portions of the pattern generated by the first exposure field to periodically recur in portions of the pattern generated by subsequent exposure fields.

FIG. 7A depicts a portion of a pattern generated by a conventional pattern generator in which sweeps are correlated with one another as described above. The portion of the pattern in FIG. 7A suffer from periodic variations.

In FIG. 7A, intervals of solid portions of the pattern are depicted as adjacent pixels (represented by circles). Each set of pixels that are adjacent in the horizontal direction constitute a first sweep used to expose a first portion of the workpiece during pattern generation. Although a resultant pattern is actually composed of solid portions, the pixels (shown as circles) of the expanded view are useful in depicting portions of a sweep.

The portion of the pattern in FIG. 7A includes a plurality of rows of pixels (represented by circles) S1-S4. Each of rows S1-S4 is generated by an individual sweep of the beam emitted by light source 51. In each row of pixels, the pixel S-B represents a CD error or other variation in each sweep. Because the sweeps are correlated to one another, sweeps S1-S4 are copies of one another, and the error represented by the pixel S-B propagates to each subsequent sweep. This generally results in a visible mura in a finished portion of the pattern on the workpiece.

FIG. 7B illustrates a portion of a pattern generated by a conventional exposure field-type system. FIG. 7C illustrates a calibrated field based upon which the pattern shown in FIG. 7B may be generated. Because the exposure fields F₁, . . . Fₙ are generated based on the same calibrated field shown in FIG. 7C (e.g., correlated to one another), the exposure fields F₁, . . . Fₙ are copies of one another, and the error E propagates to each subsequent exposure field. This also generally results in a visible mura in a finished portion of the pattern on the workpiece.

Conventionally, mura and mura artifacts may be reduced through randomization or using multiple passes, normally shifted relative to one another, of respective sweeps to generate patterns.

In conventional randomization methods, the error of the pattern generator, or the pattern itself, is randomized, but the systematic behavior of the error (and the error itself) remains. In reality, applying pure randomization to a scan of the pattern generator “smears” the systematic errors. This “smearing,” however, applies a random error in addition to the remaining original error. Because error is additive, the additional error increases the overall error. This increase in overall error may also result in an increase in overall mura or degradation of pattern fidelity such as increased CD uniformity, stitching or positioning errors.

In a conventional multi-pass method, the number of scans used by the pattern generator to generate the pattern is increased. This increase in the number of scans may reduce the statistical basis for systematic errors because the amplitude of the systematical errors, which cause mura, is reduced. In practice, however, multiple passes reduce production speed and throughput and increases the demands of system stability in regard to overlay performance, which may increase costs.

### SUMMARY

Example embodiments are directed to methods and apparatuses for mura reduction. For example, reduction of mura on a photomask.

At least one example embodiment provides a method for generating a pattern on a workpiece. The method may include generating the pattern on the workpiece by exposing the workpiece using uncorrelated sweeps of a beam of electromagnetic radiation or particles such as electrons or ions. A pattern generator may be calibrated such that each printed pixel has essentially the same error probability when printed. The exposing may expose the workpiece using the calibrated pattern generator.

The calibrating may further include: calibrating each of a plurality of sweeps or sets of sweeps originating from one or a plurality of beams of electromagnetic radiation used to generate the pattern based on at least one of different algorithms, different physical rasters and different detectors, each sweep of the beam exposing a portion of the pattern.

According to at least some example embodiments, a main sweep may be calibrated and the plurality of sweeps may be generated based on the main sweep using at least one of different algorithms, different physical rasters and different detectors. Alternatively, each of a plurality of sweeps of a beam of electromagnetic radiation used to generate the pattern may be calibrated such that errors in a portion of the pattern generated by each sweep are un-correlated errors in at least one of critical dimension (CD) and linearity. The pattern may be printed using a single or multi-pass technique.

According to example embodiments, each of the plurality of sweeps or exposure fields may be calibrated based on a different calibration map. The different calibration maps may include at least one different and at least partly un-correlated error characteristic. The at least one un-correlated error characteristic may include at least one of critical dimension (CD) errors, power distribution errors and linearity errors

At least one other example embodiment provides an apparatus for generating a pattern. The apparatus may include a pattern generating system configured to expose a workpiece using uncorrelated sweeps of a beam of electromagnetic radiation. The apparatus may further include a control system configured to calibrate each of a plurality of sweeps based on at least one of different algorithms, different physical rasters and different detectors. Each sweep of the beam may expose a portion of the pattern.

The control system may be further configured to calibrate a main sweep, and generate the plurality of sweeps based on the main sweep using at least one of different algorithms, different physical rasters and different detectors. Moreover, the control system may be configured to calibrate each of the plurality of sweeps such that errors in a portion of the pattern generated by each sweep are non-correlated errors in at least one of critical dimension (CD) and linearity. The apparatus may print the pattern using a single or multi-pass technique.

According to at least some example embodiments, the exposure field may be continuous, discrete (e.g., a point array), 1, 2 or 3 dimensional in nature. In the example embodiment of a multi-beam apparatus, a plurality of essentially parallel beams may impinge on and expose the workpiece in different sets of sweeps where the different sets of sweeps are calibrated using different calibration maps.

At least one other example embodiment provides another method for generating a pattern. This method may include generating a plurality of uncorrelated ramps, and exposing a workpiece based on the plurality of uncorrelated ramps. A sweep of a beam of electromagnetic radiation corresponding to each of the plurality of uncorrelated ramps may be generated and the workpiece may be exposed using the plurality of sweeps.

According to example embodiments of the invention using an exposure field based pattern generator, at least two different exposure fields are calibrated using at least two different calibration maps. The exposure field based pattern generator may print the pattern using a single or multi-pass technique. In using a multi-pass technique, different calibration maps may be used for different passes.

In yet another example embodiment, a plurality of calibration maps may be used for calibrating different exposure fields in a single pass by changing calibration of the exposure field(s) during the writing of the pass using a different calibration map.

At least one other example embodiment provides yet another method for generating a pattern. The method may include exposing a workpiece using at least partly uncorrelated exposure fields of a beam of electromagnetic radiation.

Example embodiments may also provide computer readable mediums storing computer executable instructions, which when executed by a computer, cause the computer to perform methods according to example embodiments.

### BRIEF DESCRIPTION OF THE DRAWINGS

The accompanying drawings are intended to depict example embodiments of the present invention and should not be interpreted to limit the scope thereof. The accompanying drawings are not to be considered as drawn to scale unless explicitly noted. The present invention will become more apparent by describing in detail example embodiments thereof with reference to the attached drawings in which:

FIG. 1 illustrates views of a conventional exposure field based pattern generator;

FIG. 2 illustrates a portion of a conventional exposure field based pattern generator;

FIGS. 3A and 3B illustrate additional examples of conventional scanning pattern generators.

FIGS. 4A and 4B illustrate portions of a conventional scanning based pattern generator;

FIG. 5 is a simplified schematic diagram of a conventional scanning pattern generator;

FIG. 6 illustrates a portion of a scanning operation used to form a plurality of scan strips;

FIG. 7A illustrates a pattern generated by a conventional pattern generator;

FIG. 7B illustrates a portion of a pattern generated by a conventional exposure field-type system;

FIG. 7C illustrates a calibrated field based upon which the pattern shown in FIG. 7B may be generated;

FIG. 8 illustrates a pattern generator according to an example embodiment;

FIG. 9 illustrates a method for generating a pattern according to an example embodiment;

FIG. 10 illustrates a method for calibrating a pattern generator according to an example embodiment;

FIG. 11A shows a portion of a pattern generated using methods and/or apparatuses according to example embodiments;

FIG. 11B shows a portion of a pattern generated using methods and/or apparatuses according to example embodiments; and

FIG. 11C illustrates a plurality of (e.g., N) uncorrelated fields based upon which the portion of the pattern shown in FIG. 11B may be generated.

### DETAILED DESCRIPTION OF EXAMPLE EMBODIMENTS

Example embodiments relate to methods for patterning media used in the manufacturing and production of accurate patterns and devices. Patterns or devices may constitute patterns used in display applications such as thin film transistor liquid crystal displays (TFT-LCDs), organic light emitting diodes (OLEDs), surface-conduction electron-emitter display (SED), plasma display panels (PDPs), field emission displays (FEDs), low temperature poly-silicon LCDs (LTPS-LCD) and similar display technologies. The patterns may further constitute sensor devices such as charge coupled device (CCD) sensors, complementary metal-oxide semiconductor (CMOS) sensors and other sensor or image pick-up technologies.

Example embodiments also relate to patterning of other devices, or material used for production of devises, such as memories (e.g., SRAM, DRAM, FLASH, ferroelectric, ferromagnetic, etc.), optical devices (e.g., gratings, scales, diffractive optical elements (DOEs), kinoforms, holograms, etc.) as well as other structures such as particular 3-D structures, imprinting stamps, offset plates, reliefs, etc.

The carrier of these accurate patterns, hereafter referred to as a workpiece, may be for example, a semiconductor wafer, a plastic material (Polyethylene Terephthalate (PET), Polyethylene Naphthalate (PEN), etc.), chrome coated quartz masks, flexible materials, metals, etc. More specific examples include glass substrates used for display manufacturing, photo masks used for lithography, semiconductor wafers, elastomer based templates, etc.

Example embodiments are described more fully hereinafter with reference to the accompanying drawings, in which example embodiments of the invention are shown. This invention may, however, be embodied in many different forms and should not be construed as limited to the example embodiments of the present invention set forth herein. Rather, these example embodiments of the present invention are provided so that this disclosure will be thorough and complete, and will fully convey the scope of the invention to those skilled in the art. In the drawings, the size and relative sizes of layers and regions may be exaggerated for clarity.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments will now be described more fully with reference to the accompanying drawings. In the drawings, like reference numerals represent like elements.

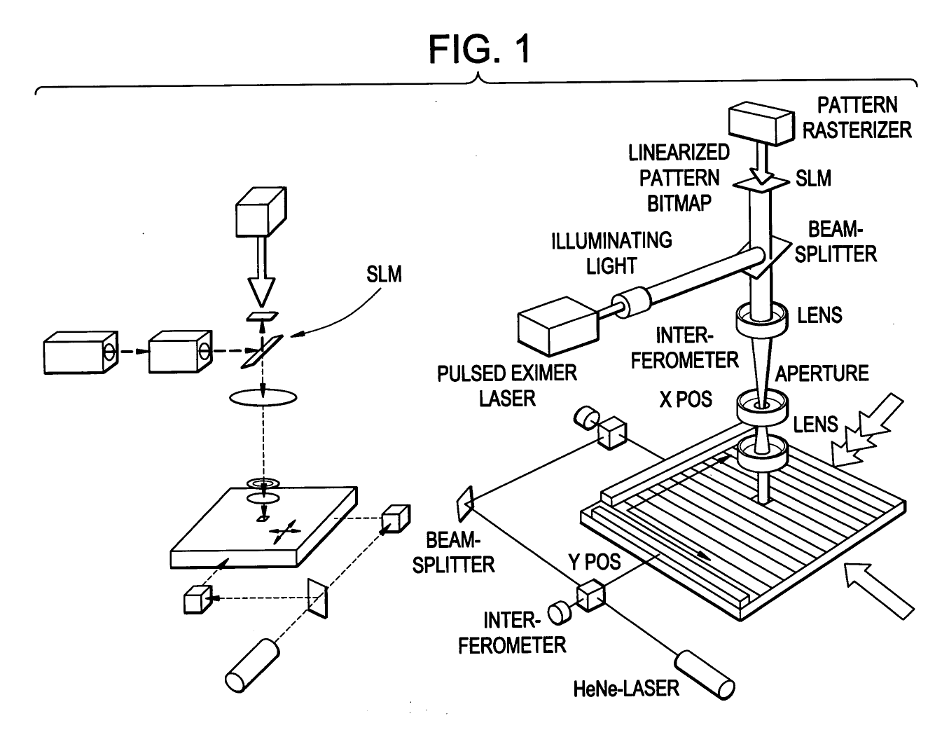

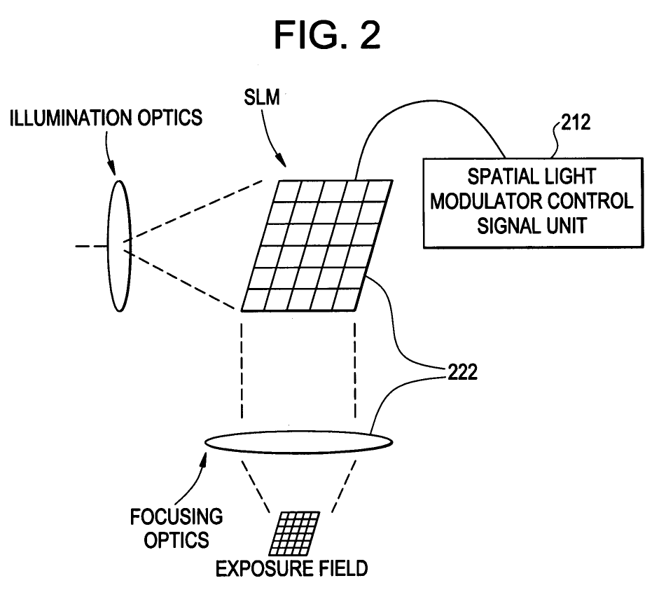

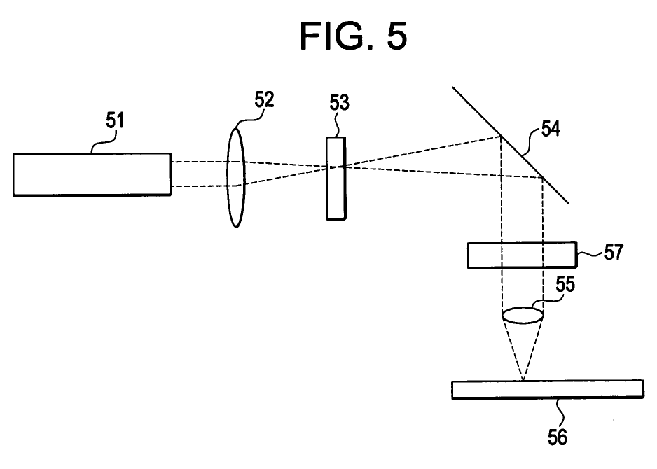

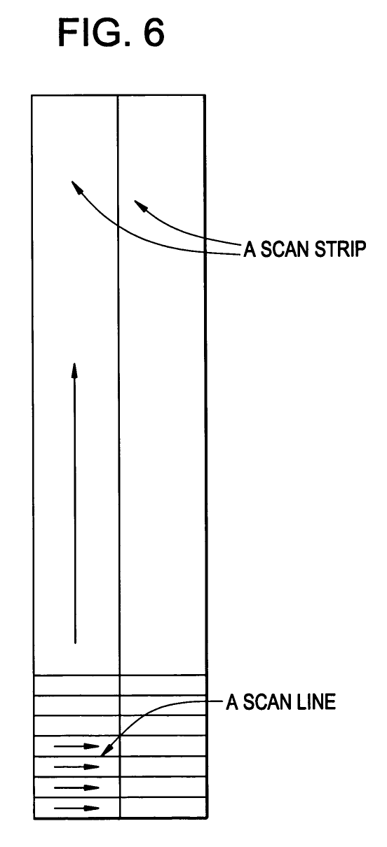

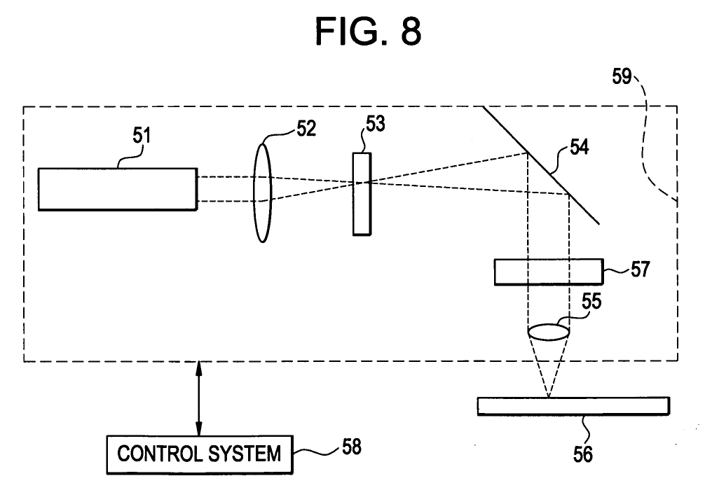

FIG. 8 illustrates a pattern generator according to an example embodiment. The pattern generator of FIG. 8 may be similar to the conventional scanning pattern generators shown in FIG. 5, but may further include a control system 58. In FIG. 8, the components of the pattern generator in FIG. 5 may be collectively referred to as a pattern generating system 59. Although illustrated as a scanning pattern generating system in FIG. 8, the pattern generating system 59 may be implemented as an exposure field based pattern generator similar to the pattern generator shown in FIG. 1.

The control system 58 may be implemented as, or at least include, a digital signal processor (DSP), an application specific integrated circuit (ASIC), a computer or the like.

The control system may include a means of storing ramps or calibration maps, such as a memory. Alternatively, the means of storing may be embodied as an external unit that accessible by the control system via a link, such as, a system bus, telecommunications link, the Internet, etc.

These stored ramps and calibration maps may include information that affects the sweep or exposure field created by the pattern generator. This information may include data records, databases, etc., which may control for example, frequency, phase or signal amplitudes, voltage, current or timing of individual parts (e.g., pixels, group of pixels, etc.), order tables containing the order in which individual pixels or groups of pixels should be exposed within a sweep, exposure field or an exposure volume for the case of 3-dimensional printing.

Because of the similarities in the scanning pattern generators shown in FIGS. 5 and 8, a discussion of common elements will be omitted for the sake of brevity.

The control system 58 may operate to control the manner in which the pattern generating system 59 generates a pattern. Depending on whether the pattern generating system is a scanning-type or exposure field type, the control system 58 may control a sweep, a scan line or how an exposure field is exposed. For example, the control system 58 may expose a workpiece using uncorrelated sweeps of a beam of electromagnetic radiation or particle beams. In doing so, each printed pixel may have, but not necessarily, essentially or substantially the same error probability.

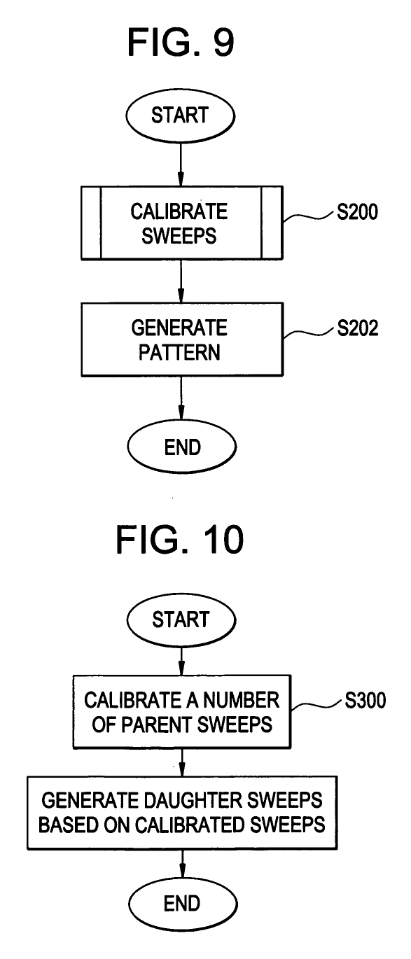

FIG. 9 is a flow chart illustrating a method for generating a pattern with reduced mura error according to an example embodiment. The method shown in FIG. 9 may be implemented on the pattern generator of FIG. 8, and for the sake of clarity will be described with respect to being performed by the control system 58 shown in FIG. 8. However, it will be understood that example embodiments of methods described herein may be implemented on or in conjunction with other pattern generators.

Referring to FIG. 9, at S200 the control system 58 may calibrate a plurality of sweeps or ramps for generating (printing or writing) a pattern on a workpiece. The plurality of sweeps may be calibrated such that each sweep or set of sweeps includes non-correlated errors in critical dimension (CD), caused by varying power distribution along a sweep (in regard to zero or other wanted power distribution), and/or linearity, or other given or predetermined local placement of certain parts of the sweep and/or other sweep artifacts. In one example embodiment, the plurality of sweeps may include 512 sweeps, but is not limited thereto.

The control system 58 may calibrate, and store, each of the plurality of sweeps or sets of sweeps individually using different rasters, different detectors, different algorithms or boundary conditions or other means of achieving at least partly uncorrelated calibrations. In this example, the individually calibrated sweeps (or ramps controlling the sweeps) may be used in a given or predetermined fashion (e.g., based on knowledge about individual sweep characteristics), or alternatively, in a random or quasi-random fashion during patterning. The usage of the different ramps during exposure may be determined before actual writing, during actual writing or a combination of the two.

The “mixing” of essentially differently calibrated (non-correlated) sweeps (ramps) when creating adjacent or at least relatively, closely positioned scan lines on a workpiece forming pattern features, results in a non-systematic patterning behavior, which reduces the appearance of mura.

Sweep calibration in a conventional pattern generator primarily refers to tuning sweep parameters (referred to as electrical ramp signals or just “ramps”) that control the generated sweeps to achieve desired properties. Calibration may include tuning these parameters to achieve a relatively constant or given sweep velocity. In at least one example, a relatively constant sweep velocity may be crucial to achieve equidistant pixels along the sweep if the pixels are delivered from a modulator at certain time intervals.

Calibration may also include tuning sweep parameters to achieve a constant or predetermined power distribution along a sweep. A constant power distribution may be crucial to achieve pixels with the same intensity distribution before deflection such that pixels have the same intensity distribution after deflection.

Calibration may also include the tuning of properties such as beam shape, focus, etc, along the distance of the sweep.

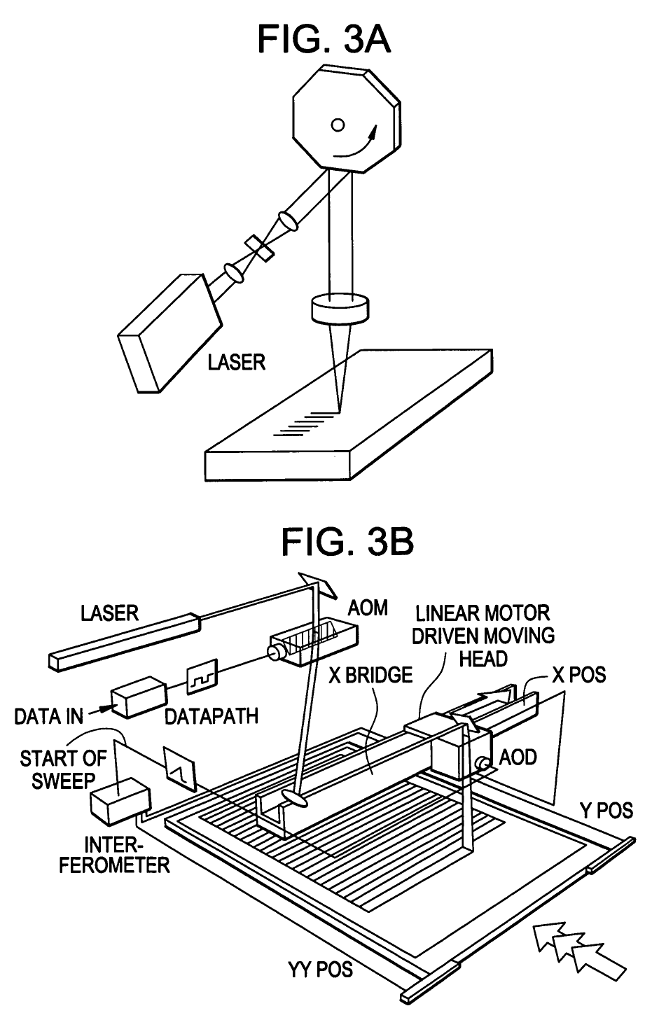

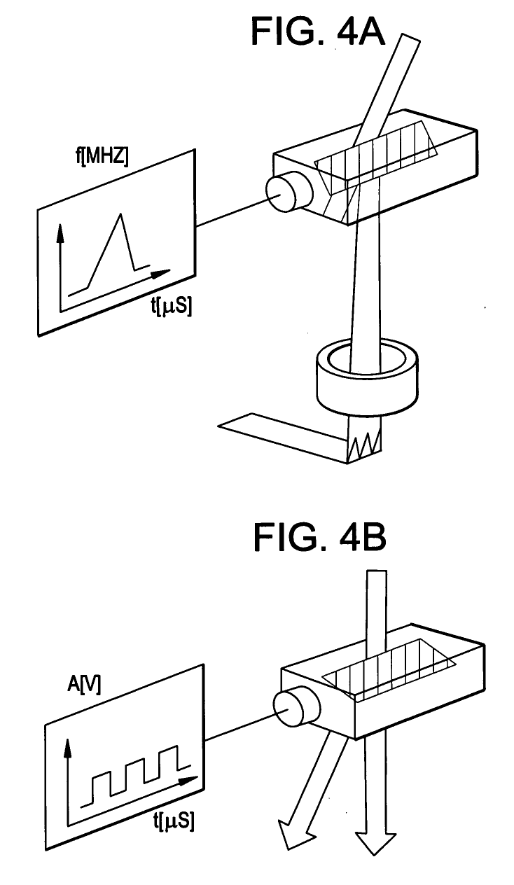

In an acousto-optical deflection (AOD) based system (e.g., as shown FIG. 3B), for example, a first calibration ramp may control sweep linearity and a second calibration ramp may control sweep power. The first ramp may be a ramp signal in which frequency varies as a function of time, whereas the second ramp may be a ramp signal in which the amplitude varies as a function of time.

While these ramp signals vary, the properties sweep linearity and sweep power may be measured using, for example, a calibration mark, detectors, reflected or transmitted light and/or external measurement equipment (e.g., measurement of written test patterns).

Based on these measurements the ramps may be calibrated to achieve desired sweep linearity and power.

More specifically, for example, in an AOD based system, the ramp controlling the power along a sweep may be calibrated by continuously scanning (e.g., by changing the frequency feed to the AOD) the beam on a photosensitive detector and changing the amplitude of the ramp to achieve desired power distribution over the sweep. To control the linearity of the sweep, the frequency ramp may be calibrated by scanning the beam across a calibrating mark and detecting the modulation of the signal on a detector. Based on that information, the linearity of the sweep may be calibrated by changing the frequency of the ramp.

In the case of an exposure field based system, calibration may include controlling properties the same as or similar to those mentioned above by array (e.g., GLV or inkjet array in a 1-D system), matrix (e.g., DMD and lens array in a 2-D system) or continuous field (SLM) geometry. Moreover, in an exposure field based system, the calibration map may be calibrated using a CCD camera, an interferometer based sensing system, a time measurement circuit, or the like.

Calibration maps may include data describing properties controlling optical and/or electrical signals (e.g., voltage, current, amplitudes, phases, frequencies, etc.), which may be used to control individual pixels in an exposure field, group of individual pixels, a continuous area of an exposure field, etc. Calibration maps may also include timing properties for individual or groups of pixels within an exposure fields as well as the order in which individual or groups of pixels or areas are to be written (e.g., writing strategy data).

A sweep may also be calibrated using a raster or other means of physical reference, or using a signal generator as calibration reference.

Referring back to FIG. 9, after calibrating sweeps at S200, the pattern generating system 59 may generate (print or write) a pattern on the workpiece at S202 by exposing the workpiece using the calibrated sweeps. The pattern may be generated using a single or multi-pass technique. In using a multi-pass technique, each pass may have a sweep offset (e.g., of half a sweep).

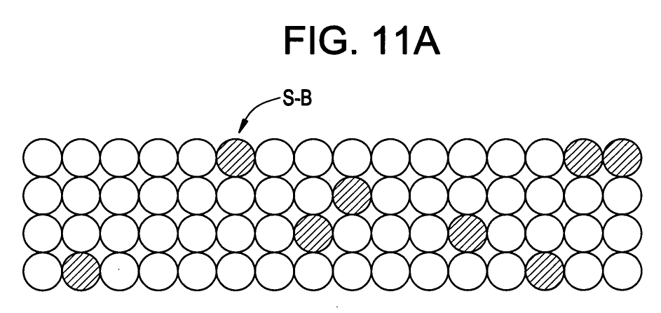

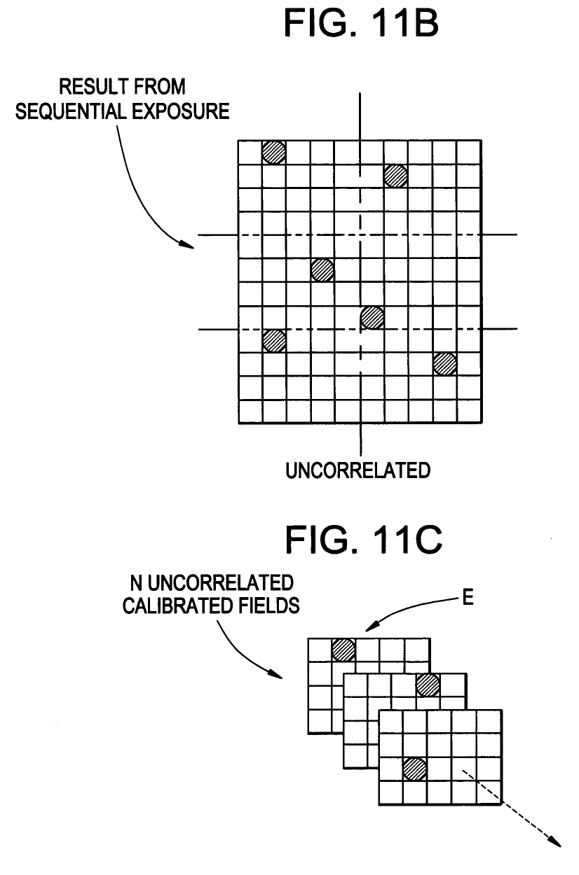

FIGS. 10 and 11 illustrate ramp calibration methods according to other example embodiments.

Referring to FIG. 10, at S300 the control system 58 may calibrate a first set of sweeps. The first set of sweeps may be calibrated using different physical rasters, detectors algorithms and/or boundary conditions or other means of achieving non-correlated sweep or ramp calibrations in the same or substantially the same manner as described above with regard to FIG. 9. According to example embodiments, the number of sweeps in the first set of sweeps may be arbitrary, but may be less than the total number of sweeps to be used in generating the pattern. Each sweep in the first set of sweeps may be referred to as a “parent sweep.”

At S302, the control system 58 may generate a plurality of “daughter” sweeps for each “parent” sweep in the first set of sweeps, thereby generating the plurality of sweeps to be used in generating the pattern. Each parent and daughter sweep may have a corresponding ramp upon which the sweep may be generated.

An example of a daughter ramp in an AOD based system may be a copy of the parent ramp with, for example, an offset in values controlling certain properties. For example, a daughter ramp controlling sweep linearity and sweep position on the workpiece (e.g., a change in frequency over time in an AOD) may be created by offsetting the parent ramp in the frequency domain. The parent ramp may be offset by adding a constant to each value in the parent ramp thereby generating the daughter ramp.

When the same parent ramp is used to create multiple daughter ramps, errors in the parent ramp may be duplicated in the daughter ramps. These duplicated errors lead to the correlated errors in all ramps used for patterning. Consequently, a patterning instance using these ramps may be more prone to systematic errors in essentially predetermined positions.

For example, a first plurality of daughter sweeps may be generated based on a first parent sweep in the first set of sweeps, a second plurality of daughter sweeps may be generated based on a second parent sweep in the first set of sweeps, and so on. In this example, each of the plurality of daughter sweeps may be correlated to its corresponding parent sweep and to other daughter sweeps generated based on the same parent sweep, but not correlated to the other parent sweeps or daughter sweeps.

Returning to FIG. 10, in an alternative, at S302 the control system 58 may generate a set of daughter sweeps based on each parent sweep in the first set of sweeps using different algorithms and/or boundary conditions. In this example, each of the plurality of daughter sweeps may be correlated only to a relatively small number of daughter or parent sweeps. In at least one example, each of the sweeps (both parent and daughter) may be unique and not correlated to any other sweep.

In another alternative, ramps (parents or daughters) may be “calibrated” or determined by guessing. This “calibration” may not include the use of any external calibration reference or algorithms based on external calibration input(s) to ensure a limited degree of correlation between the individual ramps. It follows that the exclusion of an external reference may also suppress introduction of errors caused by errors present in the omitted external reference.

According to this example embodiment, ramps and/or calibration maps may be generated based on a theoretical expected exposure field output from a given input. For example, in the case of an AOD exposure system, a first ramp may include a linear frequency ramp with a certain (or known) k-value (incline). The next ramp may include another linear frequency ramp with another k-value and so on. Each of the k-values and linear frequency ramps may be different. If the k-value is randomly chosen, ramps derived from the different values may be uncorrelated.

The method of guessing ramps, as well as the other described methods, may be effective if multiple exposure units (e.g., AODs) are used. Having different exposure units may further increase the uncorrelated behavior between exposed sweeps on the workpiece because the exposed sweeps may have individual inherent properties and may also have optical properties that differ between them. Using the same set, sub-set or similar ramps to control multiple exposure units may be advantageous from a cost perspective. If no manner of calibration exists, a plurality of ramps may be chosen randomly or arbitrarily. The random selection may result in uncorrelated ramps.

Example embodiments provide some examples for generating uncorrelated calibration control signals, ramps, sweeps and/or calibration maps. Choosing uncorrelated calibration control signals during patterning may be performed in a random or quasi-random fashion. In generating a pattern, using these uncorrelated ramps, sweeps and/or calibration maps may improve the written result. Patterning may be performed with a given or predetermined order, fashion and/or distribution in which these uncorrelated ramps are used. The use of ramp mixing strategy may or may not be based on pattern data.

During calibration, references containing know errors may be used. Using known references may provide information regarding expected errors in each individually calibrated sweeps. This knowledge may be used as input to determine the manner in which the individual sweeps should be mixed during patterning. In addition, these known references may be chosen such that the average error is essentially the same or substantially the same in all or substantially all positions along a sweep or within an exposure field if imaged or superimposed on top of each other.

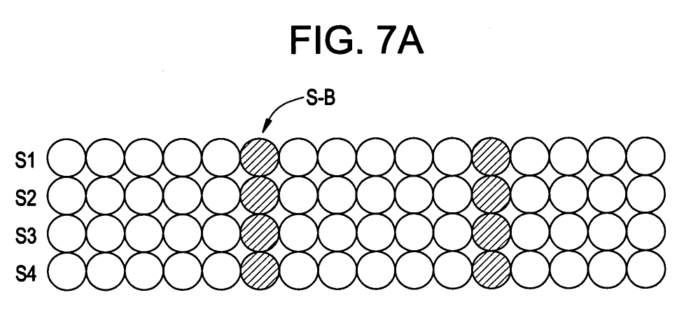

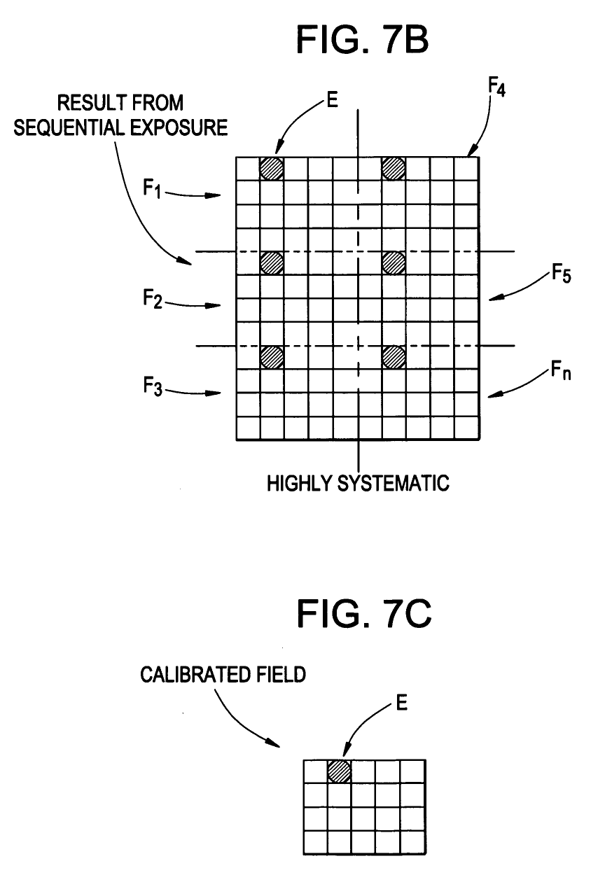

FIG. 11A shows a portion of a pattern generated using methods and/or apparatuses according to example embodiments. The portion of the pattern is represented in the same manner as the pattern shown in FIG. 7A, and thus, a pixel having a varying property such as positioning, power (CD), focus, etc. is represented by S-B.

Referring to FIG. 11A, as compared with FIG. 7A, the error present is no longer periodic, as was the case in FIG. 7A. Instead, the error is distributed. Moreover, little or no additional error is introduced, that is for example, the error magnitude of the pattern in FIG. 11A is the same or substantially the same as the error magnitude of the pattern in FIG. 7A. The lack of periodicity reduces and/or eliminates the existence of mura.

FIG. 11B shows a portion of a pattern generated using methods and/or apparatuses according to example embodiments. The portion of the pattern is represented in the same manner as the pattern shown in FIG. 7B, and thus, a pixel having a varying property such as positioning, power (CD), focus, etc. is represented by E.

Referring to FIG. 11B, as compared with FIG. 7B, the error present is no longer periodic, as was the case in FIG. 7B. Instead, the error is distributed. Moreover, little or no additional error is introduced, that is for example, the error magnitude of the pattern in FIG. 11B is the same or substantially the same as the error magnitude of the pattern in FIG. 7B. The lack of periodicity reduces and/or eliminates the existence of mura.

FIG. 11C illustrates a plurality of (e.g., N) uncorrelated fields based upon which the portion of the pattern shown in FIG. 11B may be generated. In comparison with FIG. 7C, each of the plurality of fields in FIG. 11C may include an error E, but the error E in each of the plurality of fields may be different. Accordingly, the error present in the resultant pattern generated based on the plurality of uncorrelated fields is no longer periodic. As discussed above, the lack of periodicity reduces and/or eliminates the existence of mura.

Example embodiments provide methods and apparatuses for generating/writing a pattern in which each written pixel may or may not have the same or substantially the same error probability. As a result, mura may be reduced and/or eliminated.

Methods according to example embodiments may be embodied in the form of computer-executable program instructions, recorded on computer-readable media, for causing a computer to perform the method steps/operations. The media may include, alone or in combination with the program instructions, data files, data structures, or the like. The media and program instructions may be those specially designed and constructed for the purposes of example embodiments described herein, or they may be of the kind well-known and available.

Examples of computer-readable media include magnetic media such as hard disks, floppy disks, and magnetic tape; optical media such as CD ROM disks and DVD; magneto-optical media such as optical disks; and hardware devices that are specially configured to store and perform program instructions, such as read-only memory (ROM), random access memory (RAM), flash memory, and the like.

Examples of program instructions include both machine code, such as produced by a compiler, and files containing higher level code that may be executed by the computer using an interpreter. The described hardware devices may be configured to act as one or more software modules to perform the operations of the above-described example embodiments.

Although example embodiments of the present invention have been described, it will be obvious that the same may be varied in many ways. Such variations are not to be regarded as a departure from the spirit and scope of the present invention, and all such modifications are intended to be included within the scope of the present invention.

I claim:

1. A method for generating a pattern on a workpiece, the method comprising:
calibrating at least two sweeps or exposure fields based on at least two different calibration maps;
generating the pattern on the workpiece by exposing the workpiece using said at least two sweeps or exposure fields.

2. The method of claim 1, wherein the calibrating further includes,
calibrating each of the plurality of sweeps or exposure fields based on a different calibration map, the different calibration maps including at least one different and at least partly un-correlated error characteristic.

3. The method according to claim 2, wherein the pattern is printed in 3-dimensions.

4. The method of claim 2, wherein the at least one un-correlated error characteristic includes at least one of critical dimension (CD) errors, power distribution errors and linearity errors.

5. The method according to claim 4, wherein the pattern is printed in 3-dimensions.

6. The method of claim 1, wherein the calibrating further includes,
calibrating each of the plurality of sweeps or exposure fields based on at least one of different physical rasters and different detectors.

7. The method according to claim 6, wherein the pattern is printed in 3-dimensions.

8. The method of claim 6, wherein the calibrating further includes,
calibrating each of at least two different sets of sweeps or exposure fields using a different calibration map, and
generating the at least two different sets of sweeps or exposure fields based on at least one of different algorithms, different physical rasters and different detectors.

9. The method according to claim 8, wherein the pattern is printed in 3-dimensions.

10. The method of claim 1, wherein the pattern is printed using a single or multi-pass technique.

11. The method according to claim 1, wherein the pattern is printed in 3-dimensions.

12. The method of claim 11, wherein the at least two calibration maps are 3-dimensional calibration topologies or calibration volumes.

13. The method according to claim 12, wherein the at least two calibration maps include information for controlling at least one of frequency, phase or signal amplitudes, voltages, current or timing for pixels or group of pixels, order of exposure of an individual or group of pixels, exposure field or exposure volume.

14. The method according to claim 1, wherein the at least two calibration maps include information for controlling at least one of frequency, phase or signal amplitudes, voltages, current or timing for pixels or group of pixels, order of exposure of an individual or group of pixels, exposure field or exposure volume.

15. The method of claim 1, further including, providing at least two different calibration maps.

16. An apparatus for generating a pattern on a workpiece, the apparatus comprising:
a pattern generating system configured to expose the workpiece using at least two sweeps or exposure fields of a beam of electromagnetic radiation, each of the at least two sweeps or exposure fields being calibrated using a different calibration map.

17. The apparatus of claim 16, further including,
a control system configured to calibrate a plurality of sweeps or exposure fields such that the plurality of sweeps or exposure fields includes at least one different and at least partly un-correlated error characteristic.

18. The apparatus of claim 17, wherein the at least one un-correlated error characteristic includes at least one of critical dimension (CD) errors, power distribution errors and linearity errors.

19. The apparatus of claim 17, wherein the control system calibrates each of the plurality of sweeps or exposure fields based on at least one of different physical rasters and different detectors

20. The apparatus of claim 17, wherein the control system is further configured to,
calibrate a main sweep, and
generate the plurality of sweeps based on the main sweep using at least one of different algorithms, different physical rasters and different detectors.

21. The apparatus of claim 17, wherein the control system is further configured to,
calibrate a first set of sweeps, and
generate the plurality of sweeps based on each sweep in the first set of sweeps using at least one of different algorithms, different physical rasters and different detectors.

22. The apparatus of claim 16, wherein the pattern is printed using a single or multi-pass technique.

23. The apparatus of claim 22, wherein when the pattern is printed using a multi-pass technique, different calibration maps are used for different passes.

24. The apparatus of claim 22, wherein a plurality of calibration maps may be used for calibrating different exposure fields in a single pass by changing calibration of the exposure field(s) during writing of the pass using a different calibration map.

25. A method for generating a pattern on a workpiece, the method comprising:
generating a plurality of uncorrelated ramps; and
exposing the workpiece based on the plurality of uncorrelated ramps.

26. The method of claim 25, further including,
generating a sweep of a beam of electromagnetic radiation corresponding to each of the plurality of uncorrelated ramps, and wherein
the exposing exposes the workpiece using the plurality of sweeps.

27. A method for generating a pattern on a workpiece, the method comprising:
exposing the workpiece using uncorrelated exposure fields of a beam of electromagnetic radiation.

28. A computer readable medium storing computer executable instructions that when executed cause a computer to perform the method of claim 1.

29. The computer readable medium of claim 28, wherein the method further includes,
calibrating a plurality of sweeps such that the plurality of sweeps includes non-correlated critical dimension (CD) errors, power distribution errors or linearity errors.

30. The computer readable medium of claim 29, wherein the calibrating further includes,
calibrating each of the plurality of uncorrelated sweeps based on at least one of different physical rasters and different detectors.

31. The computer readable medium of claim 29, wherein the calibrating further includes,
calibrating a first set of sweeps, and
generating the plurality of sweeps based on each sweep in the first set of sweeps using at least one of different algorithms, different physical rasters and different detectors.

32. A computer readable medium storing computer executable instructions that when executed cause a computer to perform the method of claim 25.

33. A computer readable medium storing computer executable instructions that when executed cause a computer to perform the method of claim 27.
